(19) United States
(12) Patent Application Publication
(10) Pub. No.: US 2007/0096838 A1
(43) Pub. Date: May 3, 2007

(54) Field emission electron gun

(75) Inventors: Masato Kudoh, Tokyo (JP); Yukihito Kondoh, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: JEOL Ltd., Akishima (JP)

(21) Appl. No.: 11/589,367

(22) Filed: Oct. 30, 2006

(30) Foreign Application Priority Data
Oct. 31, 2005 (JP) 2005-315686

(51) Int. Cl. H03B 9/06

(52) U.S. Cl. 331/84

(57) ABSTRACT

Electron beam equipment fitted with a field emission electron gun (FEG) having an extractor electrode, an acceleration electrode, a repeller electrode disposed between the extractor electrode and the acceleration electrode, and a repeller power supply for applying a given voltage to the repeller electrode. Electrons extracted from the emitter collide against the extractor electrode, producing secondary electrons moving toward the acceleration electrode. The secondary electrons are repelled by the repeller electrode and thus prevented from reaching the specimen.

### BACKGROUND OF THE INVENTION

1. Field of the Invention

The present invention relates to a field emission electron gun (also known as a field emission gun (FEG)) installed in an electron microscope or other similar instrument. More particularly, the invention relates to a field emission gun improved such that the amount of scattered electrons hitting a specimen surface is greatly reduced.

2. Description of Related Art

Because an FEG emits an electron beam having a quite narrow energy width and provides high brightness, the FEG is suitable for improvement of performance in terms of imaging and analysis. Therefore, FEGs are used in many electron beam instruments typified by electron microscopes. An FEG has an emitter for emitting electrons and an extractor electrode. A voltage is applied between the emitter and the extractor electrode to extract electrons from the emitter by a strong electric field formed at the tip of the emitter. FEGs are classified into the thermal type in which the emitter is heated and the cold type in which the emitter is not heated. Electrons extracted from the emitter are accelerated by acceleration electrodes or anodes and made to hit a specimen.

FIG. 1 is a schematic cross section showing an example of the structure of a prior art thermal FEG. The electron gun, generally indicated by reference numeral 1, has an emitter 2, a suppressor electrode 4 for suppressing thermal electrons produced from the side surfaces of the emitter 2, an extractor electrode 5 for extracting electrons from the emitter, and an acceleration electrode 6 for imparting a given energy to the electrons. Each electrode is shaped substantially cylindrically. Each electrode is centrally provided with a hole to permit passage of an electron beam EB. Required voltages are applied to the suppressor electrode 4 and extractor electrode 5 from a suppressor power supply 7 and an extractor power supply 8, respectively. The acceleration electrode 6 is kept at ground potential. A high negative voltage is applied to the emitter 2 from an acceleration power supply 9. The electrons emitted from the emitter pass through the holes formed in the centers of the electrodes and acquire a given energy. In the example of structure shown in FIG. 1, an emitter heating power supply 3, the suppressor electrode 4, and the suppressor power supply 7 are disposed because of the structure of the thermal FEG. In a cold FEG, these power supplies are unnecessary.

FIG. 4 is a graph showing the relation between each electrode of the prior art thermal FEG and electric potential. The potential (−V) on the optical axis of an electron beam EB is plotted on the vertical axis. The upward direction is in the negatively increasing direction. The distance from the emitter on the optical axis is plotted on the horizontal axis. The potential at the position of the emitter is a negative potential (−VA) whose absolute value is equal to the accelerating voltage. The potential at the position of the suppressor electrode is a negative potential (−VA−VS) whose absolute value is much greater than the potential at the emitter. Because a positive voltage VE is applied to the extractor electrode to extract electrons from the emitter, the potential at the position of the extractor electrode is a negative potential (−VA+VE) whose absolute value is smaller than the potential at the emitter. The potential at the position of the acceleration electrode is equal to ground potential (−V=0).

In an FEG, when electrons produced from the emitter are pulled out, an extraction voltage of about 2 to 4 kV is generally applied to the extractor electrode. In this case, not all the extracted electrons pass through the hole formed in the center of the extractor electrode. Rather, a large portion of the electrons collides against the surroundings of the hole. The voltage of about 2 to 4 kV applied to the primary electrons is in a voltage region where secondary electrons are produced at the highest efficiency by collision of the primary electrons with a metal or the like. Therefore, a large number of secondary electrons produced by collision of the primary electrons from around the hole in the extractor electrode have an acceleration voltage (VA−VE) corresponding to the voltage at the extractor electrode relative to ground and move toward the acceleration electrode.

FIG. 1 schematically shows the manner in which secondary electrons SE produced from around the center hole of the extractor electrode 5 move toward the acceleration electrode 6. The region from which electrons are produced in this way is far wider than an intended region that should be created from the emitter of the FEG. Furthermore, the energy possessed by these electrons and converted into a voltage is an acceleration voltage (VA−VE) that is lower than the intended accelerating voltage VA by an amount corresponding to the extraction voltage VE. Because the focusing conditions imposed by an electron lens located behind the acceleration electrode are different from those for electrons with accelerating voltage VA, correct focusing is not achieved. For these two reasons, if a spot of an electron beam sharply focused onto the specimen surface is created by the electrons having the intended accelerating voltage VA, a spread spot of the electron beam will be created around the former spot by electrons with lower accelerating voltages.

Obstructive electrons spreading around the correct spot of the electron beam are generally known as scattered electrons. These are schematically shown in FIGS. 7a and 7b. Distance taken on a specimen surface is plotted on the horizontal axis. The intensity distribution of the electron beam is plotted on the vertical axis. FIG. 7a shows the case in which there are no scattered electrons, and FIG. 7b shows the case in which scattered electrons having spread are produced. In the state of FIG. 7b, the resolution and image quality of electron microscope images are adversely affected. When an analysis is performed, a signal coming from outside a region to be analyzed is detected and analyzed. In this way, severe inconveniences arise (see, for example, D. W. McComb and G. C. Weatherly, Ultramicroscopy 68, 61-67 (1997)).

On the other hand, an electron gun using an electron source made of a filament of W (Tungsten) or LaB₆ (Lanthanum-hexaboride) heated to a high temperature does not have any electrode that produces a voltage difference with an accelerating voltage, such as an extractor electrode required by an FEG. In equipment fitted with an electron gun using a filament of W or LaB₆, the ratio of the intensity of scattered electrons to the intended spot of electron beam is smaller than the ratio for equipment fitted with an FEG by at least one order of magnitude. In equipment having an electron gun using no extractor electrode, electrons colliding against the surroundings of the holes of various stops formed in the electron beam path contribute mainly to scattered electrons. The directions of travel of these electrons make angles to the intended optical axis of the electron beam and so most of them can be removed by providing a stop for blocking scattered electrons (see, for example, Japanese Patent Laid-Open No. H5-275040).

However, in the case of an FEG, the trajectory of electrons produced from the wall surface of the hole formed in the center of the extractor electrode is curved by the electric field set up between the extractor electrode and the acceleration electrode. As a result, the trajectory may be coincident with the optical axis or be parallel to the optical axis in locations close to it. Scattered electrons consisting mainly of such electrons cannot be removed simply by mounting a stop in the electron beam path.

### SUMMARY OF THE INVENTION

It is an object of the present invention to provide a field emission electron gun (FEG) which can improve the resolution and image quality of electron microscope images and enhance the analytical accuracy by greatly reducing the amount of scattered electrons hitting a specimen surface.

This object is achieved in accordance with the teachings of the present invention by providing a field emission electron gun having an emitter, an extractor electrode for extracting electrons from the emitter, an acceleration electrode for accelerating the electrons extracted from the extractor electrode, a repeller electrode disposed on the opposite side of the extractor electrode from the emitter, and a repeller power supply for applying a given voltage to the repeller electrode. The given voltage applied by the repeller power supply is so determined that the potential at the repeller electrode is between the potential at the emitter and the potential at the extractor electrode.

In one embodiment of the present invention, the repeller electrode is disposed between the extractor electrode and the acceleration electrode.

In another embodiment of the present invention, the repeller electrode is disposed on the opposite side of the extractor electrode from the emitter.

According to one embodiment of the present invention, there is provided a field emission electron gun having an emitter, an extractor electrode for extracting electrons from the emitter, an acceleration electrode for accelerating electrons extracted from the extractor electrode, a repeller electrode disposed on the opposite side of the extractor electrode from the emitter, and a repeller power supply for applying a given voltage to the repeller electrode. The given voltage applied by the repeller power supply is so determined that the potential at the repeller electrode is between the potential at the emitter and the potential at the extractor electrode. Therefore, an electric field produced by the repeller electrode suppresses electrons having an acceleration voltage corresponding to the potential at the extractor electrode produced near a hole formed in the center of the extractor electrode from reaching a specimen surface. Consequently, the intensity of scattered electrons which spread outwardly from an intended spot of electron beam and bombard the specimen surface can be reduced greatly. Hence, the resolution and image quality of electron microscope images can be improved. Also, the analytical accuracy can be improved.

Other objects and features of the invention will appear in the course of the description thereof, which follows.

### BRIEF DESCRIPTION OF THE DRAWINGS

FIG. 1 is a schematic cross section showing an example of the structure of a prior art field emission electron gun;

FIG. 2 is a schematic cross section of a field emission electron gun according to a first embodiment of the present invention;

FIG. 3 is a schematic cross section of a field emission electron gun according to a second embodiment of the present invention;

FIG. 4 is a graph illustrating the relationship between the electrodes and potentials in the prior art field emission electron gun;

FIG. 5 is a graph illustrating the relationship between the electrodes and potentials in the field emission electron gun according to the first embodiment of the present invention;

FIG. 6 is a graph illustrating the relationship between the electrodes and potentials in the field emission electron gun according to the second embodiment of the present invention; and

FIGS. 7a and 7b are graphs in which a case where there exist scattered electrons spreading around a spot of electron beam is compared with a case where there are no such scattered electrons.

### DESCRIPTION OF THE PREFERRED EMBODIMENTS

Embodiments of the present invention are hereinafter described with reference with the accompanying drawings.

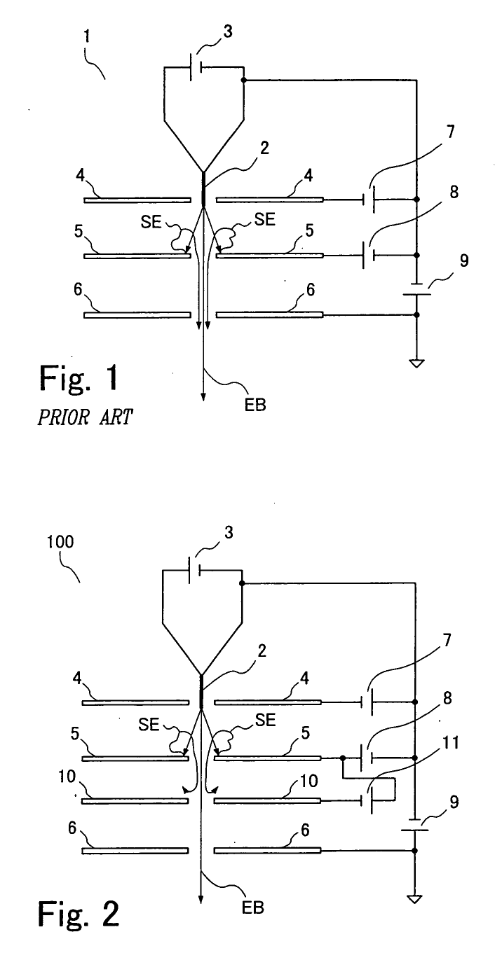

FIG. 2 schematically shows the structure of an electron gun 100 for carrying out the present invention. It is to be noted that like components are indicated by like reference numerals in both FIGS. 1 and 2 and that those components which have already been described will not be described below. In FIG. 2, a repeller electrode 10 is disposed between the extractor electrode 5 and the acceleration electrode 6. A repeller power supply 11 is mounted to apply a given voltage to the repeller electrode 10.

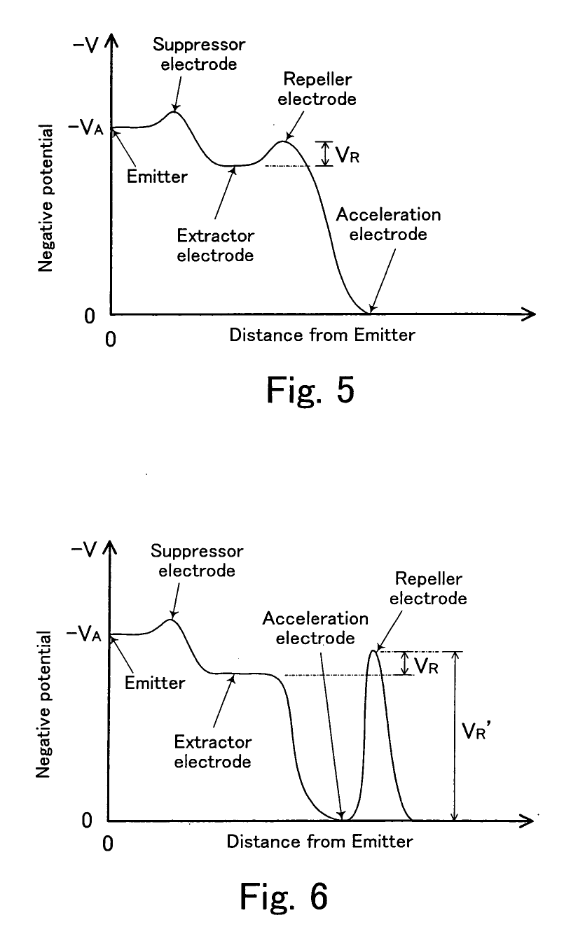

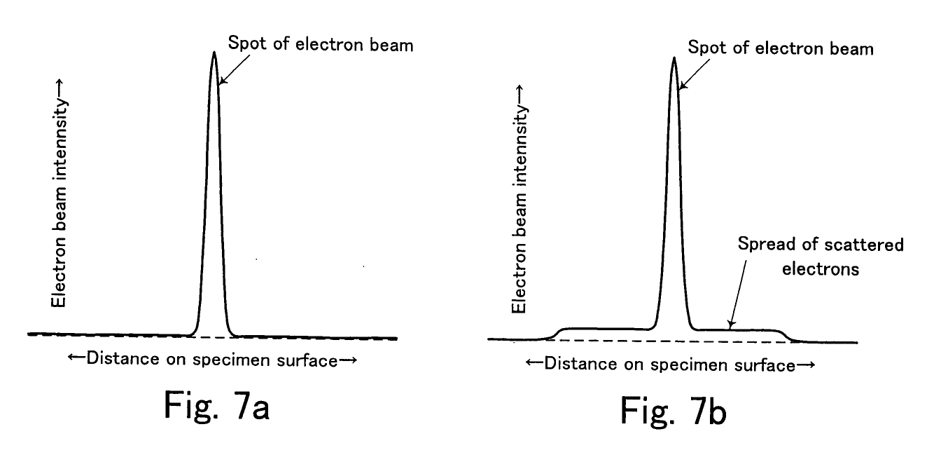

FIG. 5 is a graph illustrating the relationship between the electrodes and potentials in the electron gun 100. In the same way as in FIG. 4, the vertical axis indicates the potential (−V) on the optical axis of the electron beam EB. The negatively increasing direction is in the upward direction. The horizontal axis indicates the distance from the emitter, taken along the optical axis. The position of the suppressor electrode 4 on the optical axis is at potential (−VA−VS) and the position of the extractor electrode 5 is at potential (−VA+VE) in the same way as in FIG. 4, it being noted that these potentials are not shown in FIG. 5. The potential at the position of the acceleration electrode 6 is equal to ground potential (−V=0).

A voltage (−VR) is applied to the repeller electrode 10 to make the potential at the repeller electrode higher than the potential (−VA+VE) at the extractor electrode 5 in the negative direction to repel electrons with acceleration voltage (VA−VE) corresponding to the potential at the extractor electrode toward the acceleration electrode. That is, the position of the repeller electrode 10 on the optical axis is at potential (−VA+VE−VR). The voltage (−VR) applied to the repeller electrode is only required to set the potential at the position of the repeller electrode to a value between (−VA) and (−VA+VE). However, in practical applications, it suffices to set the voltage VR to tens of volts because energies possessed by secondary electrons and converted into voltages are only tens of volts relative to the potential at the extractor electrode, the secondary electrons being produced by collision of electrons extracted from the emitter 12 with the extractor electrode. FIG. 2 schematically shows the manner in which secondary electrons SE produced near the hole formed in the center of the extractor electrode 5 are repelled by the repeller electrode 10 when the secondary electrodes SE move toward the acceleration electrode 6.

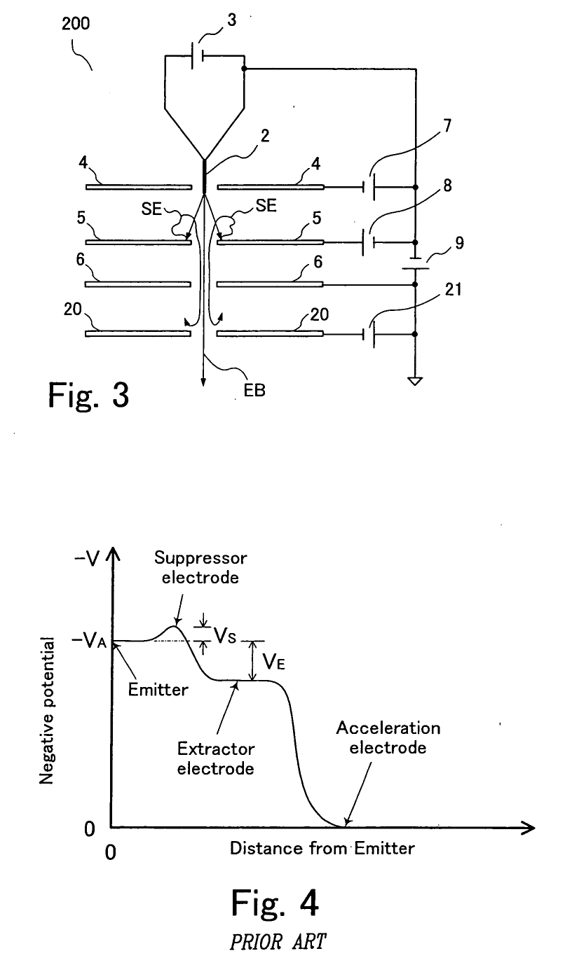

Another embodiment of the present invention is next described. FIG. 3 schematically shows an example of the structure of an electron gun 200 for implementing this embodiment of the present invention. Note that like components are indicated by like reference numerals in both FIGS. 1 and 3 and that those components which have already been described will not be described below. In FIG. 3, a repeller electrode 20 is disposed on the opposite side of the acceleration electrode 6 from the extractor electrode 5. A repeller power supply 21 is mounted to apply a given voltage to the repeller electrode 20.

FIG. 6 is a graph illustrating the relationship between the electrodes and potentials in the electron gun 200. In the same way as in FIG. 4, the vertical axis indicates the potential (−V) on the optical axis of the electron beam EB. The negatively increasing direction is taken in the upward direction. The horizontal axis indicates the distance from the emitter, taken along the optical axis. The position of the suppressor electrode 4 on the optical axis is at potential (−VA−VS) and the position of the extractor electrode 5 is at potential (−VA+VE) in the same way as in FIG. 4, it being noted that these potentials are not shown in FIG. 6. The potential at the position of the acceleration electrode 6 is equal to ground potential (−V=0).

A voltage (−VR′) is applied to the repeller electrode 10 to place the repeller electrode at a potential higher than the potential (−VA+VE) at the extractor electrode 5 in the negative direction to repel electrons having an acceleration voltage corresponding to the potential at the extractor electrode toward the acceleration electrode. The voltage (−VR′) applied to the repeller electrode is only required to set the potential at the position of the repeller electrode to a value between (−VA) and (−VA+VE).

In FIG. 3, the voltage (−VR′) is applied to the repeller electrode 20 from the repeller power supply 21 that is connected with ground potential. Alternatively, the positive potential side of the repeller electrode 20 may be so connected as to be equal to the potential at the extractor electrode. A negative voltage (−VR) may be applied to the repeller electrode 20. At this time, the potential at the position of the repeller electrode, taken on the optical axis, is (−VA+VE−VR). FIG. 3 schematically shows the manner in which secondary electrons SE produced near the hole formed in the center of the extractor electrode 5 are repelled by the repeller electrode 10 when the electrons SE move close to the acceleration electrode 6.

In the structures shown in FIGS. 2 and 3, the emitter heating power supply 3, suppressor electrode 4, and suppressor power supply 7 are mounted because of the thermal FEG. These components are not necessary in a cold FEG.

As described so far, the provision of the repeller electrode prevents secondary electrons produced near the hole formed in the center of the extractor electrode from hitting the specimen. In this way, scattered electrons spreading around the spot of electron beam can be removed. In consequence, equipment fitted with an FEG according to the present invention permits high-resolution and high-image quality electron microscope imaging by taking advantage of the performance of the FEG. Also, correct analysis is enabled.

Having thus described our invention with the detail and particularity required by the Patent Laws, what is desired protected by Letters Patent is set forth in the following claims.

The invention claimed is:

1. A field emission electron gun comprising:
an emitter;
an extractor electrode for extracting electrons from the emitter;
an acceleration electrode for accelerating the electrons extracted from the extractor electrode;
a repeller electrode disposed on the opposite side of the extractor electrode from the emitter; and
a repeller power supply for applying a given voltage to the repeller electrode,
wherein said given voltage applied by the repeller power supply is so determined that an electric potential at the repeller electrode is between an electric potential at the emitter and an electric potential at the extractor electrode.

2. A field emission electron gun as set forth in claim 1, wherein said repeller electrode is disposed between said extractor electrode and said acceleration electrode.

3. A field emission electron gun as set forth in claim 1, wherein said repeller electrode is disposed on the opposite side of said extractor electrode from said emitter.
